(19) United States
(12) Patent Application Publication
(10) Pub. No.: US 2026/0059898 A1
(43) Pub. Date: Feb. 26, 2026

(54) PHOTOSENSITIVE DIE AND MANUFACTURING METHOD THEREOF

(71) Applicant: Taiwan-Asia Semiconductor Corporation, Hsinchu City (TW)

(72) Inventors: Ming-Hung WEI, Hsinchu City (TW); Hou-Jun WU, Hsinchu City (TW)

(21) Appl. No.: 18/971,346

(22) Filed: Dec. 6, 2024

(30) Foreign Application Priority Data
Aug. 26, 2024 (TW) 113132003

(51) Int. Cl. H10F 77/30; H10F 71/00; H10F 77/50

(52) U.S. Cl. CPC H10F 77/331; H10F 71/136; H10F 71/137; H10F 77/50

(57) ABSTRACT

A photosensitive die and a manufacturing method thereof are provided. The manufacturing method includes the following steps. First, a wafer is cut to form a plurality of photosensitive dies. Secondly, the photosensitive dies are pasted onto an adhesive film. Then, the adhesive film is stretched to increase the distances between the photosensitive dies. Finally, at least one optical film is provided to cover the surfaces of the photosensitive dies.

### CROSS-REFERENCES TO RELATED APPLICATIONS

This application claims the benefit of priority to Taiwanese Patent Application No. 113132003 filed on Aug. 26, 2024, which is hereby incorporated by reference in its entirety.

### BACKGROUND OF THE INVENTION

### Field of the Invention

The present invention relates to a photosensitive die and a manufacturing method thereof, in particular, to a photosensitive die with a sidewall optical coating and a manufacturing method thereof.

### Descriptions of the Related Art

A photodiode is an electronic device that converts external optical signals into electrical signals. The core function of a photodiode is to absorb external light to detect optical signals and convert them into measurable current. This conversion is crucial for various applications, such as optical communication, optical measurement, and image creation.

The way a photodiode absorbs external light involves the use of semiconductor materials (such as silicon substrates) within the diode to absorb the incoming light. When photons enter the photodiode and are absorbed, their energy causes electrons in the valence band to transition to the conduction band for generating electron-hole pairs. These photo-generated carriers are separated by the built-in electric field within the diode and a current is generated accordingly.

However, traditional photodiodes exhibit poor efficiency in absorbing external light during practical applications, which affects the precision of photoelectric conversion. To address this issue, the industry is in need of an innovative photodiode structure to improve the efficiency of photoelectric conversion.

### SUMMARY OF THE INVENTION

The main objective of this invention is to provide an innovative photosensitive die and a manufacturing method thereof. Compared to traditional photosensitive dies of the same size, the photosensitive die in this invention has a larger surface area and angle for absorbing external light, which enhances sensitivity of the photosensitive die. The innovative manufacturing method also addresses the problem of sidewalls of traditional photosensitive dies being easily disturbed by external light, which causes erroneous signals.

To achieve the above objective, the present invention discloses a manufacturing method of a photosensitive die. The manufacturing method includes the following steps: First, a wafer is cut to form a plurality of photosensitive dies. Secondly, the photosensitive dies are pasted onto an adhesive film. Then, the adhesive film is stretched to increase the distances between the photosensitive dies. Finally, at least one optical film is provided to cover the surfaces of the photosensitive dies.

In one embodiment of a manufacturing method of a photosensitive die of the present invention, the step of cutting a wafer to form a plurality of photosensitive dies is to cut a wafer to form a plurality of flip-chip photosensitive dies.

In one embodiment of a manufacturing method of a photosensitive die of the present invention, the step of providing at least one optical film to cover the surfaces of the photosensitive dies is to provide at least one optical film that only allows light with a specific wavelength to pass through to cover upper surface and edge sidewalls of the photosensitive dies.

In one embodiment of a manufacturing method of a photosensitive die of the present invention, the step of providing at least one optical film to cover surfaces of the photosensitive dies is to deposit at least one optical film by evaporation to cover upper surface and edge sidewalls of the photosensitive dies.

In one embodiment of a manufacturing method of a photosensitive die of the present invention, the step of providing an adhesive film is to provide a high-temperature resistant adhesive film, having a protective film and an adhesive layer, the adhesive layer is formed on the protective film and is used to adhere the photosensitive dies.

In one embodiment of a manufacturing method of a photosensitive die of the present invention, the protective film is a polyester fiber film, and the adhesive layer is an acrylic layer.

In one embodiment of a manufacturing method of a photosensitive die of the present invention, the manufacturing method further comprises a step of irradiating the adhesive layer with ultraviolet light to reduce the viscosity thereof and separating the photosensitive dies from the adhesive layer subsequently.

To achieve the above objective, the present invention discloses a photosensitive die which comprises a flip-chip photosensitive die body and at least one optical film, directly covering an upper surface and edge sidewalls of the flip-chip photosensitive die body, wherein the at least one optical film only allows light with a specific wavelength to pass through the flip-chip photosensitive die body so an electrical signal is formed correspondingly after the flip-chip photosensitive die body receives the light.

In one embodiment of the photosensitive die of the present invention, the photosensitive die is one of a photodiode, a phototransistor and an optocoupler.

In one embodiment of the photosensitive die of the present invention, the photosensitive die further comprises a pair of positive and negative electrodes, disposed on a side of the flip-chip photosensitive die body uncovering by the at least one optical film.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a schematic diagram of a wafer with a plurality of dicing lanes and photosensitive dies in an embodiment of the present invention;

FIG. 2 is a schematic diagram of a plurality of photosensitive dies adhered to an adhesive film in an embodiment of the present invention;

FIG. 3 is a side view schematic diagram of a flip-chip photosensitive die adhered to an adhesive film in an embodiment of the present invention;

FIG. 4 is a schematic diagram of a flip-chip photosensitive die fully covered by as an optical film in an embodiment of the present invention; and

FIG. 5 is a schematic diagram of the process steps of manufacturing photosensitive dies of the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

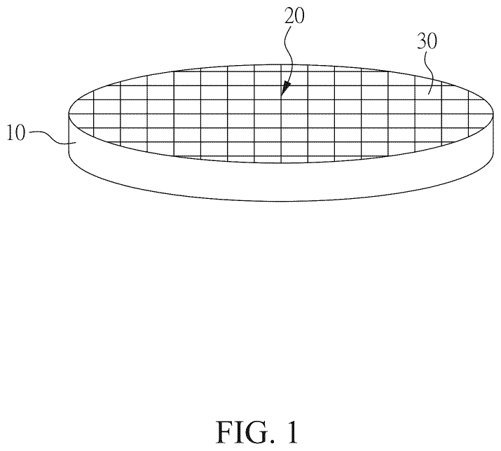

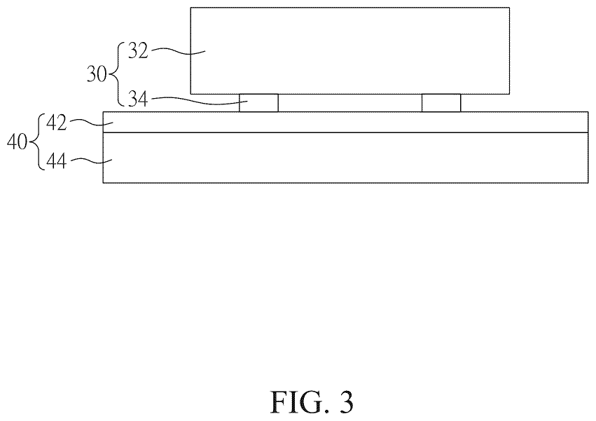

Please refer to FIG. 1, which shows a wafer 10 with a plurality of dicing lanes 20 and multiple undiced photosensitive dies 30 between each of the dicing lanes. In this embodiment, these photosensitive dies 30 are configured to receive external light and generate corresponding electrical signals. Specifically, the photosensitive dies 30 may be, but not limited to, photodiodes, phototransistors, optocoupler dies, and other photosensitive devices. Taking a photodiode as an example, the photosensitive die 30 in one embodiment of the present invention is a flip-chip photodiode, comprising a flip-chip photosensitive die body 32 and a pair of positive and negative electrodes 34 (as shown in FIG. 3). The positive and negative electrodes 34 are both disposed on the same bottom side of the flip-chip photosensitive die body 32. In detail, the flip-chip photosensitive die body 32 mainly contains a PN junction (not shown), formed by a P-type and an N-type compound semiconductor layer, which serves as the light-active region. The PN junction forms a depletion region at the interface between the P-type and N-type compound semiconductor layers. This region has no free carriers and has an internal electric field. When external light enters the flip-chip photosensitive die body 32 with sufficient energy, it excites electrons to jump to the conduction band to form electron-hole pairs. These electron-hole pairs are separated by the built-in electric field, with electrons moving toward the N-type region and holes moving toward the P-type region. Thereby, an electrical signal proportional to the intensity of the incident light is formed.

After the wafer 10 completes the growth process for the P-type and N-type compound semiconductor layers of the photosensitive dies 30, in traditional processes for photosensitive devices, the entire wafer 10 is placed into a coating machine to undergo an optical film evaporation process. The optical film only allows light with a specific wavelength to pass through and enter the light-active region of the photosensitive dies for blocking other wavelengths. After the optical coating of the wafer 10 is completed, the wafer is diced along the dicing lanes 20 to form multiple photosensitive dies 30. However, this optical coating process only forms optical films on the upper surfaces of the photosensitive dies 30 and leaves the sidewalls of the dies uncovered by optical films. As a result, these sidewalls fail to effectively absorb light and may even allow ambient light to enter the dies through the sidewalls and cause disturbances and erroneous electrical signals generated. Therefore, increasing the surface area and angle for light reception to improve the photosensitive capability, while eliminating unwanted external light interference, is the main objective of the present invention.

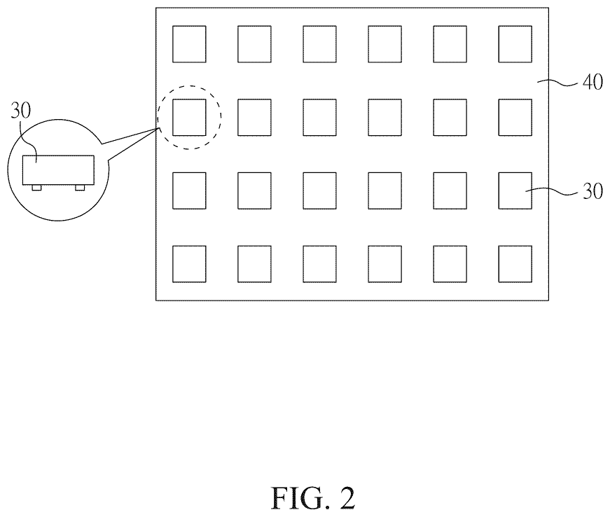

Please refer to FIG. 2 and FIG. 3. Unlike the traditional process, in the present invention, after the wafer 10 completes the growth of the compound semiconductor layers, it does not immediately undergo the optical film coating process. Instead, the wafer is first diced along the dicing lanes 20 to form multiple photosensitive dies 30, which are then individually adhered to an adhesive film 40 and arranged in an appropriate array. As shown in FIG. 2, at this moment, the photosensitive dies 30 on the adhesive film 40 are spaced apart by an appropriate distance. In a preferred embodiment, the adhesive film 40 is heat-resistant and resistant to acid and alkali. It includes a protective film 44 and an adhesive layer 42 formed thereon, as shown in FIG. 3, to adhere the photosensitive die 30. Specifically, the adhesive layer 42 is an acrylic layer that reduces its viscosity when exposed to ultraviolet light for making it easier to separate the photosensitive die from the adhesive film in subsequent processes. The protective film 44, on the other hand, is a polyester film for providing heat and chemical resistance.

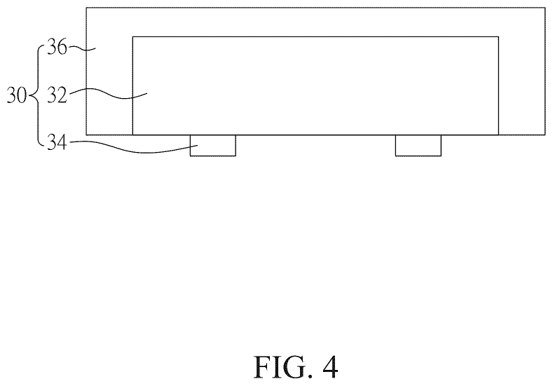

Please refer to FIG. 4. Next, an optical coating process is carried out. Unlike traditional processes, in the present invention, the entire adhesive film 40 with the adhered photosensitive dies 30 is sent into the coating machine for optical coating. The adhesive film 40 is appropriately stretched to increase the distance between the photosensitive dies 30. As mentioned earlier, since the photosensitive dies 30 are already diced and spaced apart on the adhesive film 40, one or more layers of optical film 36 are formed by evaporation during the coating process to fully cover the surfaces of the photosensitive dies 30. Specifically, the optical film 36 covers the upper surface and sidewalls of each flip-chip photosensitive die body 32, except for the bottom side of the die body 32, which remains uncovered.

The manufacturing method disclosed in the present invention allows one or more layers of optical film 36 are formed on the upper surface and sidewalls of the photosensitive dies 30 depending on practical demands. This enables precise control over the range of wavelengths entering the light-active region of the photosensitive dies. For example, the optical film 36 is a band-pass filter (BPF) composite layer composed of tantalum pentoxide (Ta2O5) and silicon dioxide (SiO₂) for selectively allowing light of a specific wavelength, such as ultraviolet light in the range of 100-400 nm, to pass through and be received by the light-active region of the flip-chip photosensitive die body 32, while blocking other wavelengths such as visible light and far-infrared light. As mentioned previously, the flip-chip photosensitive dies manufactured by the method of the present invention improve the coverage of the optical coating on the photosensitive dies for the sidewalls, which could not be coated in traditional methods, being effectively utilized. As a result, the photosensitive dies of the present invention have larger light-receiving areas and angles of the sidewalls compared to traditional dies of the same size. This gives the photosensitive dies of the present invention higher photoreceptive current gain. Furthermore, the complete coverage of the sidewalls by the optical film in the present invention also prevents external light interference from entering through the sidewalls, which cause erroneous signals in traditional photosensitive dies.

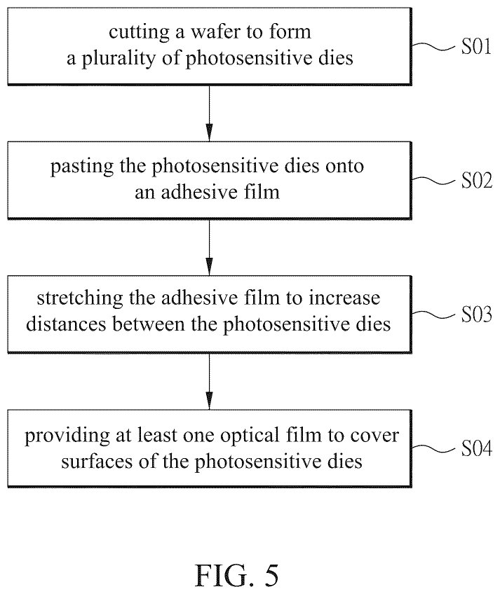

Please refer to FIG. 5, which shows a flow chart of the manufacturing steps of the photosensitive die in the present invention. First, in step S01, a wafer is diced to form multiple photosensitive dies. Next, in step S02, the photosensitive dies are adhered to an adhesive film. Then, in step S03, the adhesive film is stretched to increase the distance between the photosensitive dies. Finally, in step S04, at least one optical film is provided to cover the surfaces of the photosensitive dies. The details of the components can be referred to in the previous descriptions and will not be repeated here.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A manufacturing method of a photosensitive die, comprising:
cutting a wafer to form a plurality of photosensitive dies;
pasting the photosensitive dies onto an adhesive film;
stretching the adhesive film to increase distances between the photosensitive dies; and
providing at least one optical film to cover surfaces of the photosensitive dies.

2. The manufacturing method of claim 1, wherein the step of cutting a wafer to form a plurality of photosensitive dies is to cut a wafer to form a plurality of flip-chip photosensitive dies.

3. The manufacturing method of claim 1, wherein the step of providing at least one optical film to cover the surfaces of the photosensitive dies is to provide at least one optical film that only allows light with a specific wavelength to pass through to cover upper surface and edge sidewalls of the photosensitive dies.

4. The manufacturing method of claim 1, wherein the step of providing at least one optical film to cover surfaces of the photosensitive dies is to deposit at least one optical film by evaporation to cover upper surface and edge sidewalls of the photosensitive dies.

5. The manufacturing method of claim 1, wherein the step of providing an adhesive film is to provide a high-temperature resistant adhesive film, having a protective film and an adhesive layer, the adhesive layer is formed on the protective film and is used to adhere the photosensitive dies.

6. The manufacturing method of claim 5, wherein the protective film is a polyester fiber film, and the adhesive layer is an acrylic layer.

7. The manufacturing method of claim 6, further comprising a step of irradiating the adhesive layer with ultraviolet light to reduce the viscosity thereof and separating the photosensitive dies from the adhesive layer subsequently.

8. A photosensitive die, comprising:
a flip-chip photosensitive die body; and
at least one optical film, directly covering an upper surface and edge sidewalls of the flip-chip photosensitive die body,
wherein the at least one optical film only allows light with a specific wavelength to pass through the flip-chip photosensitive die body so an electrical signal is formed correspondingly after the flip-chip photosensitive die body receives the light.

9. The photosensitive die of claim 8, wherein the photosensitive die is one of a photodiode, a phototransistor and an optocoupler.

10. The photosensitive die of claim 8, further comprising a pair of positive and negative electrodes, disposed on a side of the flip-chip photosensitive die body uncovering by the at least one optical film.
